(19) United States
(12) Patent Application Publication
(10) Pub. No.: US 2011/0233624 A1
(43) Pub. Date: Sep. 29, 2011

(54) SEMICONDUCTOR DEVICE AND MANUFACTURING METHOD OF THE SAME

(75) Inventor: Takayoshi FUJISHIRO, Kanagawa (JP)

(73) Assignee: RENESAS ELECTRONICS CORPORATION, Kanagawa (JP)

(21) Appl. No.: 13/051,379

(22) Filed: Mar. 18, 2011

(30) Foreign Application Priority Data
Mar. 26, 2010 (JP) 2010-072294
Dec. 13, 2010 (JP) 2010-276786

(51) Int. Cl. H01L 29/772; H01L 21/336

(52) U.S. Cl. 257/288; 438/299; 257/E29.242; 257/E21.409

(57) ABSTRACT

One aspect of the present invention is a semiconductor device includes: source and drain regions; a gate electrode formed on the source and drain regions; a sidewall formed on a side surface of the gate electrode; a first silicide film formed on the source and drain regions a predetermined distance away from the sidewall; and a second silicide film formed on the gate electrode a predetermined distance away from the sidewall.

### CROSS-REFERENCE TO RELATED APPLICATIONS

This application is based upon and claims the benefit of priority from Japanese Unexamined Patent Applications No. 2010-072294, filed on Mar. 26, 2010 and No. 2010-276786, filed on Dec. 13, 2010, the disclosure of which is incorporated herein in its entirety by reference.

### BACKGROUND

The present invention relates to a semiconductor device, and more specifically to a semiconductor device including a protection transistor that prevents an internal circuit from a surge such as static electrical charge.

Recently, in a semiconductor device, along with minimization of elements, a thickness of each layer decreases and a circuit resistance is likely to be larger at everything. As a result, it causes a reduction in a circuit operation speed. Therefore, a diffusion process using a salicide (self-aligned silicide) process is performed in a manufacturing process in the semiconductor device to achieve a high-speed circuit operation. In the salicide process, with the aim of reducing a resistance component of an element, a metal such as a Ti, a Co or the like is deposited on an upper surface of each of a gate electrode, a source region, and a drain region which constitute a transistor, and a heat treating is performed to alloy the metal.

However, in an electrostatic breakdown protection element provided in an external input/output terminal in the semiconductor device, resistance in a drain region of the protection transistor becomes lower by the silicide process. Therefore, when a discharge current caused by static electrical charge flows into a drain region, charge is likely to concentrate in an edge of drain region located directly below a silicide film near a side surface of the gate electrode, which facilitates occurrence of local heat destruction.

As a result, the semiconductor device manufactured by the salicide process has a quite low static breakdown tolerance value.

Under this background, a variety of semiconductor devices having a high static breakdown tolerance value and operating in high speed have been studied (See Japanese Unexamined Patent Application Publication Nos. 07-106567 and 2006-156664).

For example, Japanese Unexamined Patent Application Publication No. 07-106567 discloses an invention related to a semiconductor device having a silicide gate electrode in a protection transistor used in an input/output portion to obtain a high static breakdown tolerance value.

FIG. 4 is a cross-sectional view showing a structure of a semiconductor device according to Japanese Unexamined Patent Application Publication No. 07-10656. An N-channel MOS transistor including a polysilicon gate electrode 116, a drain region 117 and a source region 118 is formed on a semiconductor substrate 101 with a gate oxide film interposed therebetween. Titanium silicide films 119, 120, 122, 121 and 123 are formed on the polysilicon gate electrode 116, the drain region 117 and the source region 118. Contact portions with metal lines 124 and 125 are formed on the Ti silicide films 122 and 123. The metal line 124 is connected to an input/output terminal and the metal line 125 is connected to a VSS (GND) terminal, for example.

The Ti silicide films 120 and 122 are separated from each other so that a diffusion resistance 135 is ensured between the drain regions under the Ti silicide films 120 and 122. In the same manner, the Ti silicide films 121 and 123 on the source region 118 are also separated. In other words, the Ti silicide film 119 formed on the gate electrode 116, the Ti silicide film 120 formed on the drain region 117 and the Ti silicide film 121 formed on the source region 118 are self-aligned, however, a space between the Ti silicide films 120 and 122 formed on the drain region 117 and a space between the Ti silicide films 121 and 123 formed on the source region 118 are not self-aligned with the Ti silicide films 119, 120 and 121.

In the semiconductor device having the structure mentioned above, each of the Ti silicide films 120 and 122 on the drain region 117 and the Ti silicide films 121 and 123 on the source region 118 are separated, respectively. Therefore, when a surge voltage is applied to the input/output terminal, the diffusion resistance 135 between the Ti silicide films 120 and 122 and the diffusion resistance 136 between the Ti silicide films 121 and 123 absorbs an energy of surge discharge, thereby ensuring the high static breakdown tolerance value.

Further, because of the Ti silicide film 119 formed on the polysilicon gate electrode 116, a gate electrode having a low resistance value can be obtained and a high speed circuit operation can be realized. That is, the protection transistor having the high static breakdown tolerance value and including the silicide film on the gate electorode can be obtained.

On the other hand, Japanese Unexamined Patent Application Publication No. 2006-156664 discloses a semiconductor device configured to transfer a heat generated in the semiconductor device in the aim of increasing ESD (Electostatic Discharge) tolerance value. FIG. 5 is a cross-sectional view showing a structure of the semiconductor device according to Japanese Unexamined Patent Application Publication No. 2006-156664.

A gate electrode 208 is formed on a channel 211 provided in a diffusion layer region 203 with a gate insulator film 207 interposed therebetween. A sidewall 209 is formed in a sidewall portion of the gate electrode 208 and a silicide protection film 210 is formed on the gate electrode 208 and a part of source and drain regions 205 to cover the gate electrode 208 and the sidewall 209. A metal silicide film 206 is formed to be adjacent to the silicide protection film 210 on a part of the source and drain regions 205 where the silicide protection film 210 is not formed. The silicide protection film 210 is composed of at least one of SiC film and SiOC film.

### SUMMARY

The present inventor has found a problem to be improved in the above mentioned semiconductor devices. Firstly, the semiconductor device shown in FIG. 4 has a problem that an increase in the area of the protection transistor increases the area of the semiconductor device, thereby increasing a manufacturing cost.

The semiconductor device in FIG. 4 has a structure in which the silicide film of the drain portion is separated. That is, the metal line 124 connected to an external terminal is connected to the drain region 117 through the silicide film 122. The metal line 124 has a structure to connect to the silicide film 120 through the diffusion resistance 135, which is a resistance component of the drain region, and further connect to a drain region directly below a side surface of the gate electrode on the drain region side, that is, in a channel direction.

Referring to FIG. 6, a problem of the semiconductor device in FIG. 4 will be explained. A drain region needs to have a distance (a size) in which the Ti silicide film 120, the diffusion resistance 135, the Ti silicide film 122 are arranged in a line so as to achieve the structure in which the diffusion resistance 135 is provided between the Ti silicide films 120 and 122, and the Ti silicide films 120 and 122 are separated from each other. In the same manner, the source region also needs to have a distance (a size) where the Ti silicide film 121, the diffusion resistance 136, and the Ti silicide film 123 are arranged in a line so as to achieve the structure in which the diffusion resistance 136 is provided between the Ti silicide films 121 and 123 and the Ti silicide films 121 and 123 are separated from each other. Therefore, an element size of the protection transistor needs to be large.

That is, in Japanese Unexamined Patent Application Publication No. 07-10656, a Ti film (not shown) is formed on the whole surface, the Ti film formed in a region where the Ti silicide film is not to be formed on the source and drain regions 117 and 118 is removed by etching, and a heat treatment is performed to form the Ti silicide film so that the Ti silicide film is formed on the gate electrode 116 and the diffusion resistances 135 and 136 are formed in the source and drain regions 117 and 118. Therefore, the region where the Ti film is removed (that is, a region where the diffusion resistances 135 and 136 are formed) is arranged in the other area than a periphery of steps in both sides of the gate electrode 116, so that there is no need to consider a margin for an alignment tolerance of resist mask in an etching process of Ti film or the like to form the diffusion resistances 135 and 136. That is, the element size needs to be larger by L1 plus L2 which are dimensions of the Ti silicide films 120 and 121 to ensure a margin L1 in a side of the drain region 117 and a margin L2 in a side of the source region 118.

On the other hand, in the semiconductor device shown in FIG. 5, a metal silicide film is not formed on the gate electrode 208 and the metal silicide film 206 of the source and drain regions 205 is formed away from the sidewall 209 of gate electrode 208. Therefore, there is no salicide film formed area having a size of L1 plus L2 shown in FIG. 6 and an element size can be reduced. However, the semiconductor device has a problem that a gate resistance component increases and a circuit operation speed becomes slow because the metal silicide film is not formed on the gate electrode 208.

As described above, the semiconductor device according to Japanese Unexamined Patent Application Publication No. 07-106567 has a problem that the miniaturization in the element size of the protection transistor is difficult and an increase in the size of the protection transistor increases the size of the semiconductor device, thereby increasing a manufacturing cost. On the other hand, the semiconductor device according to Japanese Unexamined Patent Application Publication No. 2006-156664 does not have a problem of increasing dimension in the protection transistor as Japanese Unexamined Patent Application Publication No. 07-10656. However, it has a problem that, since the metal silicide film is not formed on the gate electrode, it reduces the speed in the circuit operation.

A first aspect of the present invention is a semiconductor device including: a source and drain regions; a gate electrode formed on the source and drain regions; a sidewall formed on a side surface of the gate electrode; a first silicide film formed on the source and drain regions a predetermined distance away from the sidewall; and a second silicide film formed on the gate electrode a predetermined distance away from the sidewall.

Another aspect of the present invention is a manufacturing method of a semiconductor device including: forming a source and drain regions and a gate electrode on a semiconductor substrate; forming a sidewall on a side surface of the gate electrode; forming a first silicide film on the source and drain regions a predetermined distance away from the sidewall; and forming a second silicide film on the gate electrode a predetermined distance away from the sidewall.

As described above, an area where the silicide film is not formed is arranged on the source and drain regions and an area where the silicide film is not formed is arranged on the gate electrode the predetermined distances away from the sidewall. Therefore, a charge concentration is mitigated and a static breakdown tolerance value can be improved, thereby increasing the static breakdown tolerance value.

### BRIEF DESCRIPTION OF THE DRAWINGS

The above and other aspects, advantages and features will be more apparent from the following description of certain embodiments taken in conjunction with the accompanying drawings, in which:

FIG. 1 is a plain view showing a layout of a semiconductor device according to a first embodiment of the present invention;

FIG. 2 is a simplified plain view showing a sectional layout of the semiconductor device according to the first embodiment of the present invention;

FIG. 3 is a cross-sectional view of FIG. 1 taken along the line III-III;

FIG. 4 is a cross-sectional view of a semiconductor device according to Japanese Unexamined Patent Application Publication No. 07-106567;

FIG. 5 is a cross-sectional view of the semiconductor device according to Japanese Unexamined Patent Application Publication No. 2006-156664; and

FIG. 6 is a cross-sectional view for explanation of a problem in FIG. 4.

### DETAILED DESCRIPTION

The present inventor has studied in a protection transistor in which time constant does not increase, thereby preventing speed down in circuit operation of the protection transistor without increasing size. Particularly, the present inventor has studied in a protection transistor satisfying both conditions where a silicide process is performed on a gate electrode to decrease a gate resistance and not performed on some parts of the source and drain regions, which are a periphery of directly below a side surface of the gate electrode where charge is likely to be concentrated by an electrostatic breakdown to prevent a decrease in a static breakdown tolerance value.

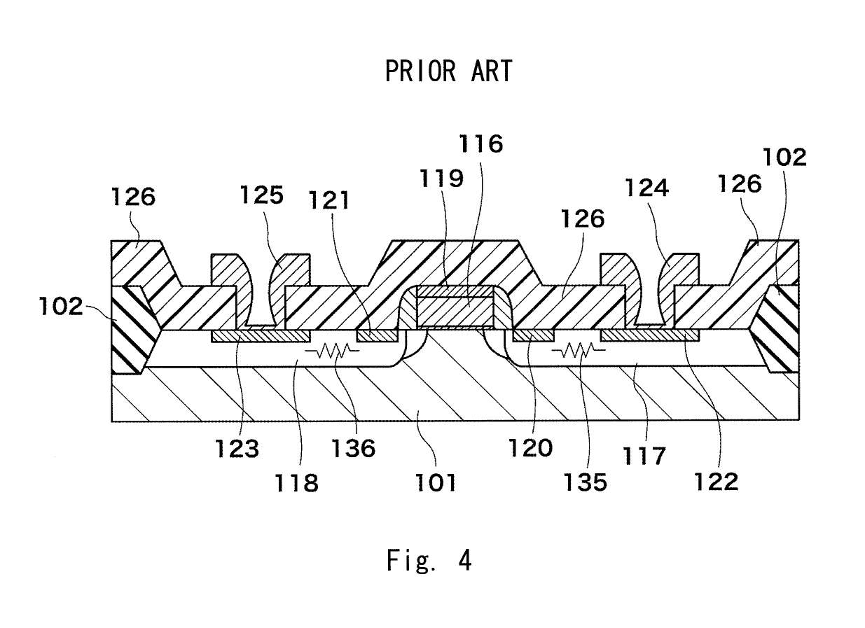

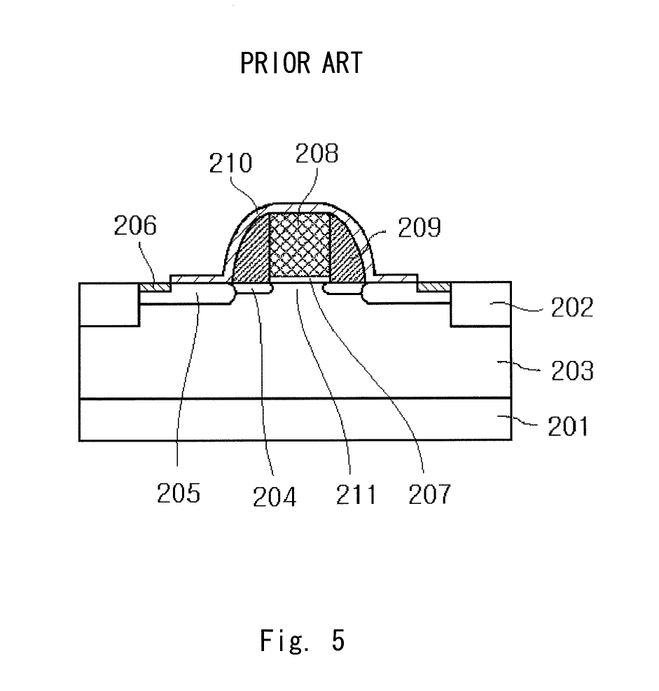

As a result, the present inventor invents a semiconductor device capable of reducing an element size of the protection transistor and to reduce a gate resistance. The protection transistor has an element size smaller than the semiconductor device shown in FIG. 4 and a gate resistance lower than the semiconductor device shown in FIG. 5 and approximately equal to the related art in FIG. 4. Therefore, the semiconductor device in which the time constant does not increase, the circuit operation speed of the protection transistor does not become lower, a charge concentration is mitigated, and a static breakdown tolerance value becomes larger can be provided.

Hereinafter, referring to drawings, a preferable embodiment of the present invention will be described. The following description and illustration are arbitrarily omitted or simplified for clearly explanation. The same reference numbers are given to components or corresponding portions having the same configurations or the same functions in each drawing so that an explanation of it is omitted.

### Embodiment

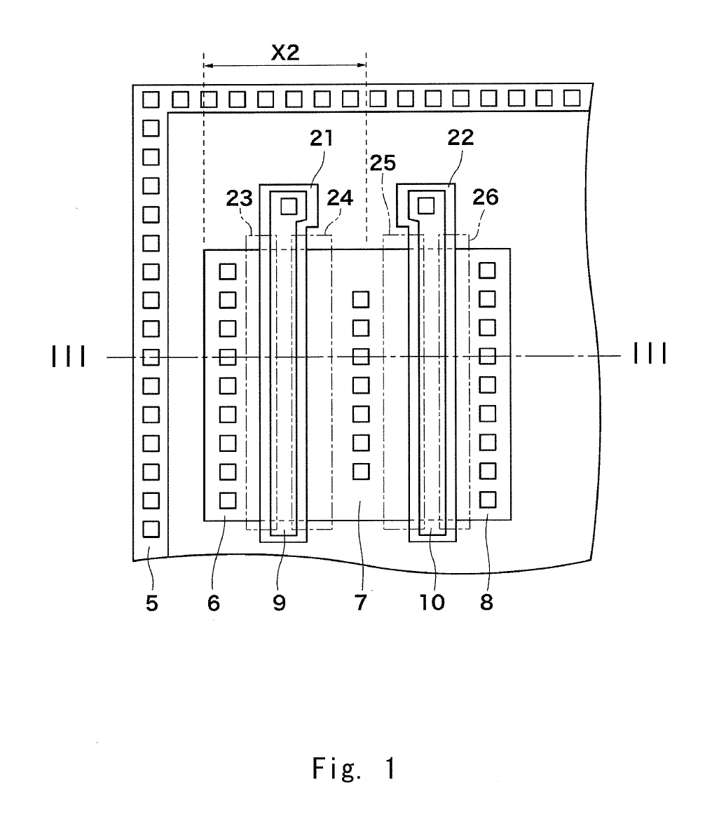

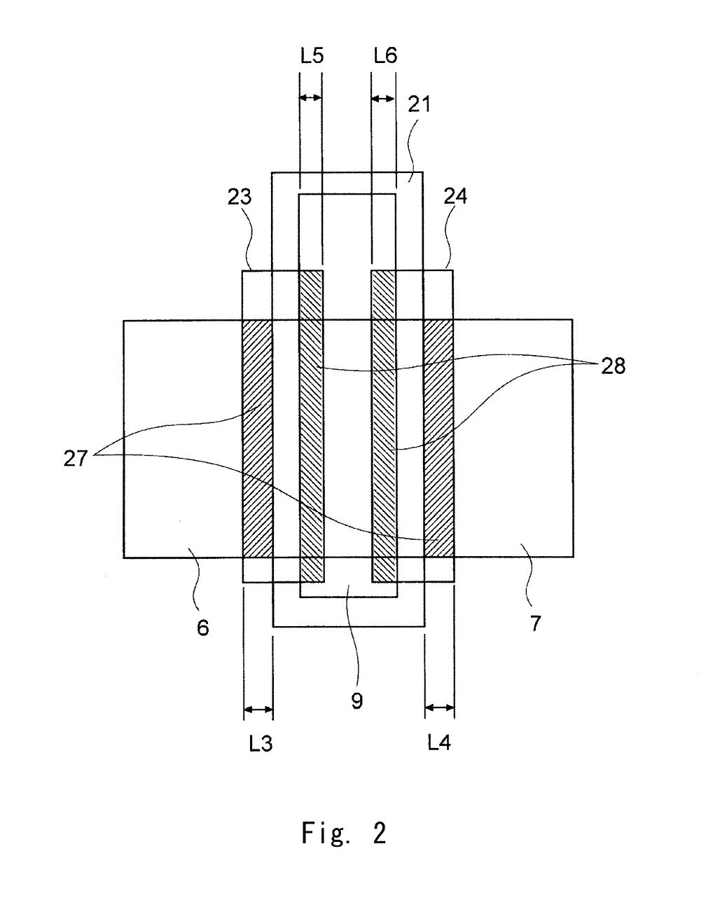

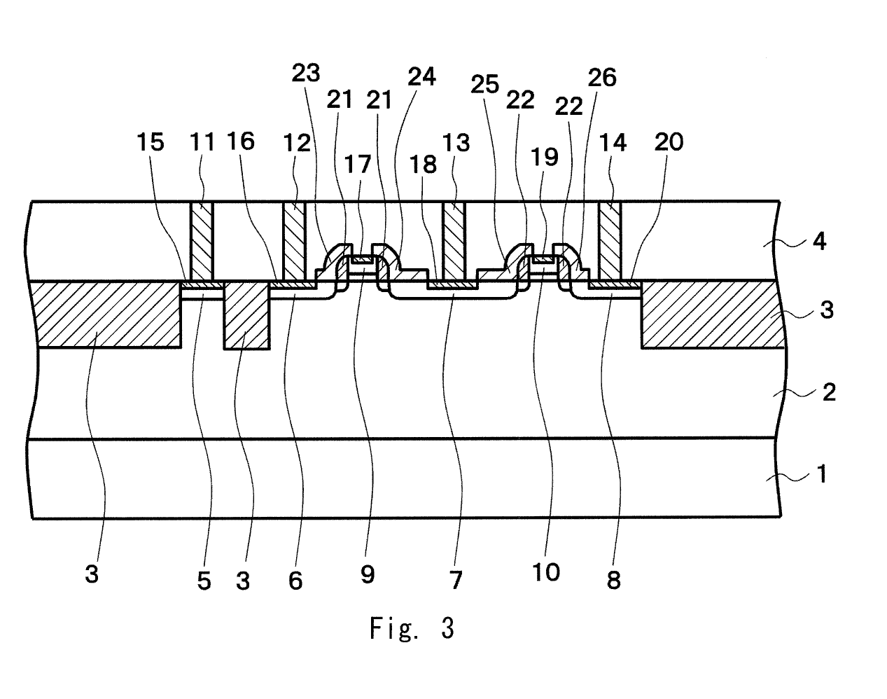

FIG. 1 is a plain view showing a layout of a semiconductor device according to an embodiment of the present invention, FIG. 2 is a simplified plain view showing a sectional layout of the semiconductor device according to the embodiment of the present invention, and FIG. 3 is a cross-sectional view of FIG. 1 taken along the line III-III. The semiconductor device of the present invention can be applied not only to an input/output portion but also to an input portion and an output portion.

For example, as shown in FIGS. 1 and 3, a P-well 2 is formed on a P-type semiconductor substrate 1, thereby forming a protection transistor. Adjacent protection transistors are arranged to share an N-type drain region 7 located in a center of them. In right and left sides of the N-type drain region 7, gate electrodes 9 and 10 and N-type source regions 6 and 8 are formed so that the protection transistors are arranged in parallel. In periphery of the protection transistor, a P-well tap 5 of a P-type diffusion layer is arranged to supply a voltage to the P-well 2. In side surfaces of the gate electrodes 9 and 10, gate electrode sidewall portions 21 and 22 are arranged. Further, Shallow Trench Isolation (STI) oxide films 3 are formed adjacent to the N-type source regions 6 and 8 in opposite sides to the N-type drain region 7. On the STI oxide film 3, a PSG insulating film 4 or the like is formed. In surfaces of the P-well tap 5, the N-type source regions 6 and 8, the N-type drain region 7, and the gate electrodes 9 and 10, silicide films 15, 16, 20, 18, 17 and 19 are formed. Instead of using only the P-type semiconductor substrate, an N-type semiconductor substrate, a SOI (Silicon On Insulator) substrate or the like can be used as the semiconductor substrate 1. The silicide films 17 and 19 are formed predetermined distances away from the gate electrode sidewall portions 21 and 22.

As shown in FIGS. 1 and 2, silicide inhibition areas 23, 24, 25 and 26 are formed. Specifically, as shown in FIG. 2, a silicide inhibition area 27 (that is, an upper surface of the source and drain regions 6 and 7), which is a part of the silicide inhibition areas 23 and 24, is not to be silicided. Further, a silicide inhibition area 28 (that is, an upper surface of the gate electrode 9), which is a part of the silicide inhibition areas 23 and 24, is not silicided.

As shown in FIG. 3, the N-type drain region 7 is connected to the silicide film 18 with ohmic contact and to the external input/output terminal through a contact plug 13 and a line (not shown). The N-type source regions 6 and 8 are respectively connected to the silicide films 16 and 20 with ohmic contact and GND (ground) potential through contact plugs 12 and 14, and lines (not shown). A back gate of the protection transistor is connected with the P-well tap 5 which is connected to the silicide film 15 with ohmic contact and GND potential through a contact plug 11.

The semiconductor device according to the present embodiment will be specifically described. As shown in FIG. 3, the protection transistors are arranged in parallel while centering on the silicide film 18 and the contact plug 13 and connected to them in parallel.

A manufacturing method of the semiconductor device according to the present embodiment will be described. In the P-well 2, the STI oxide film 3 is formed, a gate insulating film is formed, and the gate electrodes 9 and 10 are formed on them by patterning. The depthless of N-type source and drain regions with low impurity concentration are formed in a self alignment manner with respect to the gate electrodes 9 and 10. Next, for example, after an insulating film such as an oxide film is formed on a whole surface by Chemical Vapor Deposition (CVD), the oxide film is etched back to from the gate electrode sidewall portions 21 and 22 are formed in side surfaces of the gate electrodes 9 and 10. The N-type source and drain regions 6, 7 and 8 are formed in a self alignment manner with respect to the gate electrodes 9 and 10 and the gate electrode sidewall portions 21 and 22. On the other hand, the P-well tap 5 is formed in the P-well 2, which is located in a region sandwiched by the STI oxide films 3.

Next, for example, another insulating film such as an oxide film is formed on a whole surface by CVD and patterning is performed so that the oxide film is left in the silicide inhibition areas 23, 24, 25 and 26. Specifically, after the oxide film is formed on the whole surface including the gate electrodes 9 and 10 and the gate electrode sidewall portions 21 and 22, a photo-resist film (not shown) is formed on the silicide inhibition areas 23, 24, 25 and 26. An etching process is performed on the oxide film using the photo-resist film as a mask so that the oxide film is left in the silicide inhibition areas 23, 24, 25 and 26. A metal film (for example, Ti) is deposited to form a silicide film and annealing treatment is performed so that the metal film is alloyed to form the silicide filmsl6, 17, 18, 19 and 20. A remaining metal film (not shown) which is not formed a silicide film is removed by wet-etching, for example.

At this time, because the metal film formed on the STI oxide film 3 (see FIG. 3) and the oxide film which turns to be the gate electrode sidewall portions 21 and 22 is not formed a silicide film, the remaining metal film is removed. Therefore, as shown in FIG. 2, in a surface of the N-type drain region 7, the silicide film 18 is not formed on an area which is the silicide inhibition area 27 (a shaded area) but is formed only on a surface of the N-type drain region 7 other than the shaded area. In the same manner, in a surface of the N-type source region 6, the silicide film 16 is formed in other area than the silicide inhibition area 27 (a shaded area).

In the same manner, in a surface of the gate electrode 9, the silicide film 17 is formed in other area than the silicide inhibition area 28 (a shaded area)

In the N-type drain region 7 in a side of the gate electrode 10 and surfaces of the gate electrode 10 and the N-type source region 8, the silicide films 18, 19 and 20 are formed in other area than the silicide inhibition areas 25 and 26.

As shown in FIG. 3, the silicide films 16, 17, 18, 19 and 20 are formed a predetermined distance away from the sidewalls 21 and 22 in side surface of the gate electrodes 9 and 10.

Distances (sizes) L3, L4, L5 and L6 of the silicide inhibition areas 27 and 28 in a direction of gate length are determined in view of a margin for an alignment tolerance at forming a mask pattern and an increase in dimension of the silicide film or the like. That is, even if the alignment shift happens at forming the silicide inhibition areas 23 and 24, it is designed so that the gate electrode sidewall portions 21 and 22 are not exposed. Further, the silicide films 17 and 19 left in the center of the gate electrodes 9 and 10 is formed to have a predetermined width or more.

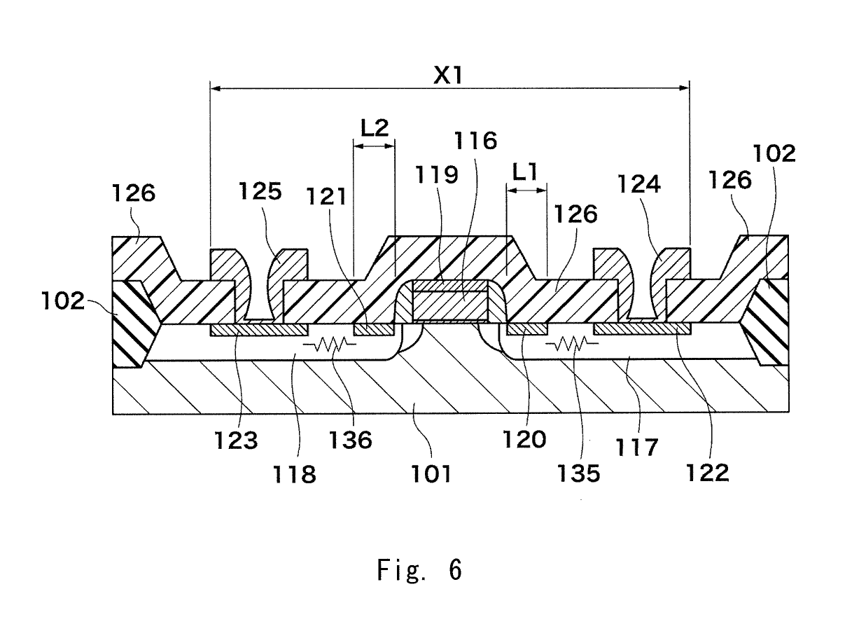

According to the above configuration, even if the alignment shift of the photoresist film occurs at etching process of the oxide film to form the silicide inhibition areas 23 and 24 or the like, it is possible to form the silicide films 6 and 7 in the source and drain regions a predetermined distance away from the gate electrode sidewall portions 21 and 22, and also to form the silicide films 17 and 19 having the predetermined width on the gate electrodes 9 and 10 as well. As a result, the distance (a size) corresponding to L1 plus L2 in the semiconductor device in FIG. 6 can be reduced, the diffusion resistance can be formed in the source and drain regions, thereby reducing a gate resistance.

It is assumed that in a manufacturing process where a gate oxide film of the above mentioned protection transistor has, for example, thickness of about 8 nm, an overwrap margin overwrapped on the gate electrode in view of alignment margin is approximately 0.2 μm. Comparing both element sizes, the element size (X1 in FIG. 6) of one protection transistor in Japanese Unexamined Patent Application Publication No. 07-106267 (FIG. 4) is estimated to be approximately 4.0 μm. On the other hand, the lengths L1 and L2 of the silicide films 120 and 121 need approximately 0.5 μm. Therefore, in the semiconductor device according to the present embodiment, these portions can be eliminated, thereby reducing the size by approximately 1.0 μm.

On the other hand, when a width of the silicide film left in the center on the gate in the semiconductor device according to the present embodiment is ensured equally to Japanese Unexamined Patent Application Publication No. 07-106267, a gate length (a gate electrode width) increases by approximately 0.4 μm. Even if the gate length increases like this, the protection transistor can be manufactured with the element size (X2 in FIG. 1) per one transistor of approximately 3.4 μm at most thereby reducing the size of the protection transistor by approximately 0.6 μm per one transistor.

The reason why the width of the silicide film left in the center on the gate is ensured equally to a related art (Japanese Unexamined Patent Application Publication No. 07-106267) is that the widths of the remaining silicide films are designed to be approximately equal to each other and the gate resistances are approximately equal to set both delay times in circuit operations at rising edge and falling edge approximately equal.

Some parts of the source and drain portions, which are the periphery of directly below the side surface of the gate electrode where charge is most likely to be concentrated by the electrostatic breakdown are not formed a silicide film thereon so that these parts are supplied with the diffusion resistance components of the source and drain portions, thereby preventing a decrease of a static breakdown tolerance value. Further, the silicide film is left in the center portion of the upper side of the gate electrode, thereby suppressing the resistance component of the gate electrode. As a result, by the protection transistor in which a time constant does not increase and the circuit operation speed is not reduced, the semiconductor device having a small element size can be provided. Note, “the periphery of directly below the side surface of the gate electrode” includes not only an area directly below the side surface of the gate electrode but also the peripheral area around it.

In the semiconductor device according to the present embodiment, the semiconductor device can be manufactured using minimum component elements because one silicide film is left on each of the source and drain regions and the silicide film is not formed in an unneeded area. Therefore, the element size of the electrostatic protection transistor can be reduced.

Further, the resistance component of the gate terminal can be suppressed approximately equally to the related art without increasing the time constant and decreasing the circuit operation speed of the protection transistor because the silicide film having resistance value approximately equally to a resistance value of a silicide film in the gate terminal arranged in the related art is left in the center portion of the gate terminal.

Further, the source and drain portions in a periphery of directly below the side surface of the gate electrode are areas where charge is most likely to concentrate and the silicide film is not formed in the periphery of the source and drain portions. Therefore, a charge concentration can be mitigated and the static breakdown tolerance value can be improved.

In the present embodiment of the present invention, the silicide films 17 and 19 are formed separating the predetermined distance away from the gate electrode sidewall portions 21 and 22. Therefore, even if the alignment shift occurs at forming the silicide films 17 and 19, a distance between adjacent silicide films 16, 17, 18, 19 and 20 can be ensured by the widths of the gate electrode sidewall portions 21 and 22.

With reducing widths (the widths L5 and L6 of 28 shown in FIG. 2) of the area where the silicide film is not formed in the upper portion of the gate electrodes 9 and 10, that is, distances between the siliside films 17 and 19 and the gate electrode sidewall portions 21 and 22, the gate resistance value becomes smaller and the operation speed becomes higher. Therefore, the silicide films 17 and 19 are formed the predetermined distance away from the gate electrode sidewall portions 21 and 22 in view of the alignment shift. On the other hand, the widths (the widths L3 and L4 of 27 shown in FIG. 2) of the upper portion of the source and drain regions 6 and 7, where the silicide film is not formed, that is, the distances between the silicide films 16, 18 and 20 and the gate electrode sidewall portions 21 and 22 need predetermined distances capable of ensuring a required static breakdown tolerance value. However, according to the present invention, the widths L1 and L2 shown in FIG. 6 can be eliminated and the element size can be reduced. Therefore, by setting the width of the area where the silicide film is not formed to minimum, the element size of the protection element can be reduced while keeping reliability.

While the invention has been described in terms of the embodiment, those skilled in the art will recognize that the invention can be practiced with various modifications within the spirit and scope of the appended claims and the invention is not limited to the examples described above.

In the above description, an example where the N-type source and drain regions are formed in the P-well 2 is explained. However, the conductivity types can be made inverse. Although, Ti is explained as a metal film to form the silicide film, for example, but W, Mo, Co and Ta can be applied as the metal film. The oxide film is explained as an insulator film forming the silicide inhibition area, but SiON film, SiN film or the like can be applied. A wet-etching and a dry-etching can be applied for removing the remaining metal film which is not formed silicide film.

Further, the scope of the claims is not limited by the embodiments described above.

Furthermore, it is noted that, Applicant's intent is to encompass equivalents of all claim elements, even if amended later during prosecution.

What is claimed is:

1. A semiconductor device comprising:
source and drain regions;
a gate electrode formed on the source and drain regions;
a sidewall formed on a side surface of the gate electrode;
a first silicide film formed on the source and drain regions a predetermined distance away from the sidewall; and
a second silicide film formed on the gate electrode a predetermined distance away from the sidewall.

2. The semiconductor device according to claim 1, wherein the first silicide film formed on the source and drain regions and the second silicide film formed on the gate electrode have end surfaces restricted by insulating films in sidewall sides.

3. The semiconductor device according to claim 2, wherein the insulating films are oxide films.

4. A manufacturing method of a semiconductor device comprising:
forming source and drain regions and a gate electrode on a semiconductor substrate;
forming a sidewall on a side surface of the gate electrode;
forming a first silicide film on the source and drain regions a predetermined distance away from the sidewall; and
forming a second silicide film on the gate electrode a predetermined distance away from the sidewall.
